(19) United States
(12) Patent Application Publication
(10) Pub. No.: US 2015/0003021 A1
(43) Pub. Date: Jan. 1, 2015

(54) INVERTER MODULE

(71) Applicant: Chicony Power Technology Co., Ltd., New Taipei City (TW)

(72) Inventor: Hung-Jui CHANG, New Taipei City (TW)

(21) Appl. No.: 13/931,886

(22) Filed: Jun. 29, 2013

(51) Int. Cl. H05K 7/02

(52) U.S. Cl. CPC H05K 7/02
USPC 361/728

(57) ABSTRACT

An inverter module converts a DC current generated by a photovoltaic panel to an AC current. The inverter module includes a housing and a PCB. The housing has a through hole. The PCB is received within the housing. An inverter circuit and a connection circuit are welded on a side of the PCB. The connection circuit includes a plurality of conductive terminals and a plurality of diodes. The conductive terminals are arranged in a row and adjacent to the through hole. Each of the conductive terminals is electrically connected to the inverter circuit. Each of the diodes is disposed between and electrically connected to the two neighboring conductive terminals thereof. By means of the integration of the inverter circuit, conductive terminals, and diodes, the space occupied by the inverter module can be reduced.

### BACKGROUND OF THE INVENTION

1. Field of the Invention

The present invention relates to an inverter of a photovoltaic panel and in particular to an inverter module integrated with an inverter and a junction box.

2. Description of Related Art

The energy resources of the earth are increasingly exhausted, leading to the energy crisis which causes people to develop the concept of energy-saving. In order to deal with such a problem, people consume the existing energy resources more economically; also, the development of new alternative energy resources has been becoming an import topic. Thus, so far, the inexhaustible sunlight energy apparently seems to be the best alternative energy resource

A general photovoltaic panel converts the sunlight energy to output a DC current via photovoltaic conversion. However, the DC current has to be converted into the AC current for delivery. Thus, an inverter is required for the photovoltaic panel to carry out DC-to-AC conversion and then to make the delivery. The current photovoltaic panel is bridge connected to the inverter using a junction box, which causes an awkward installation and occupies larger space.

In view of this, the inventor pays special attention to research with the application of related theory and tries to overcome the above disadvantages, which becomes the goal of the inventor's improvement.

### SUMMARY OF THE INVENTION

One objective of the present invention is to provide an inverter module integrating an inverter and a junction box.

To achieve the above objective, the present invention provides an inverter module, which is used to convert a DC current generated by a photovoltaic panel to an AC current. The inverter module comprises a housing and a PCB. The housing is cut through to form a through hole. The PCB is received within the housing. An inverter circuit and a connection circuit comprising a plurality of conductive terminals and a plurality of diodes are welded on a side of the PCB. The conductive terminals are arranged in a row and adjacent to the through hole. Each of the conductive terminals is electrically connected to the inverter circuit. Each of the diodes is disposed between and electrically connected to the two neighboring conductive terminals thereof.

Preferably, in the above-mentioned inverter module, the housing further comprises a box body and a cover body. The box body has an opening and a base panel opposite to the opening. The cover body is hinged to a side of the opening to cover the opening.

Preferably, in the above-mentioned inverter module, the through hole is cut and disposed in the box body.

Preferably, in the above-mentioned inverter module, the through hole is cut and disposed on the base panel of the box body.

Preferably, in the above-mentioned inverter module, an outer edge of the base panel extends to form a locking panel which has a locking hole thereon.

Preferably, in the above-mentioned inverter module, an outer side of the base panel of the box body is hollowed to form a heat dissipating space.

Preferably, in the above-mentioned inverter module, a thermal pad is attached to the PCB and contacts the housing.

Preferably, in the above-mentioned inverter module, a cut opening is formed on the PCB. The inverter circuit comprises a plurality of electronic components, one of which is disposed in the cut opening.

Preferably, in the above-mentioned inverter module, a pair of output ports is disposed on an outer side of the box body. Each of the output ports is electrically connected to the inverter circuit.

Preferably, in the above-mentioned inverter module, a side of the PCB is disposed adjacent to the through hole. The conductive terminals are arranged in a row along the side of the PCB. The inverter circuit and the connection circuit are configured in separate areas.

The inverter module of the present invention whose inverter circuit, terminals, and diodes are integrated and disposed on the same PCB can reduce the space occupied by the inverter module.

### BRIEF DESCRIPTION OF DRAWING

FIG. 1 is a perspective exploded schematic of the inverter module according to the preferred embodiment of the present invention;

FIG. 2 is a perspective schematic of the inverter module according to the preferred embodiment of the present invention;

FIG. 3 is another perspective schematic of the inverter module according to the preferred embodiment of the present invention;

FIG. 4 is a cross-sectional view of the inverter module in FIG. 3;

FIG. 5 is an arrangement view of the inverter module according to the preferred embodiment of the present invention;

FIG. 6 is another arrangement view of the inverter module according to the preferred embodiment of the present invention; and

FIG. 7 is a cross-sectional view of the inverter module in FIG. 6 in an arrangement state.

### DETAILED DESCRIPTION OF THE INVENTION

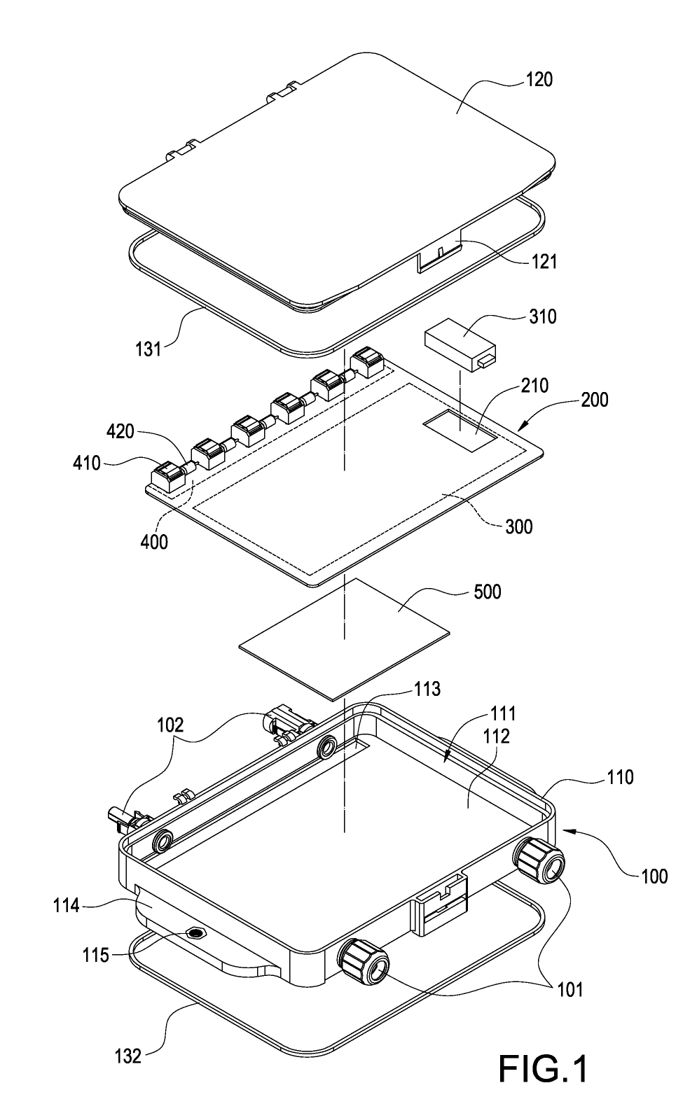

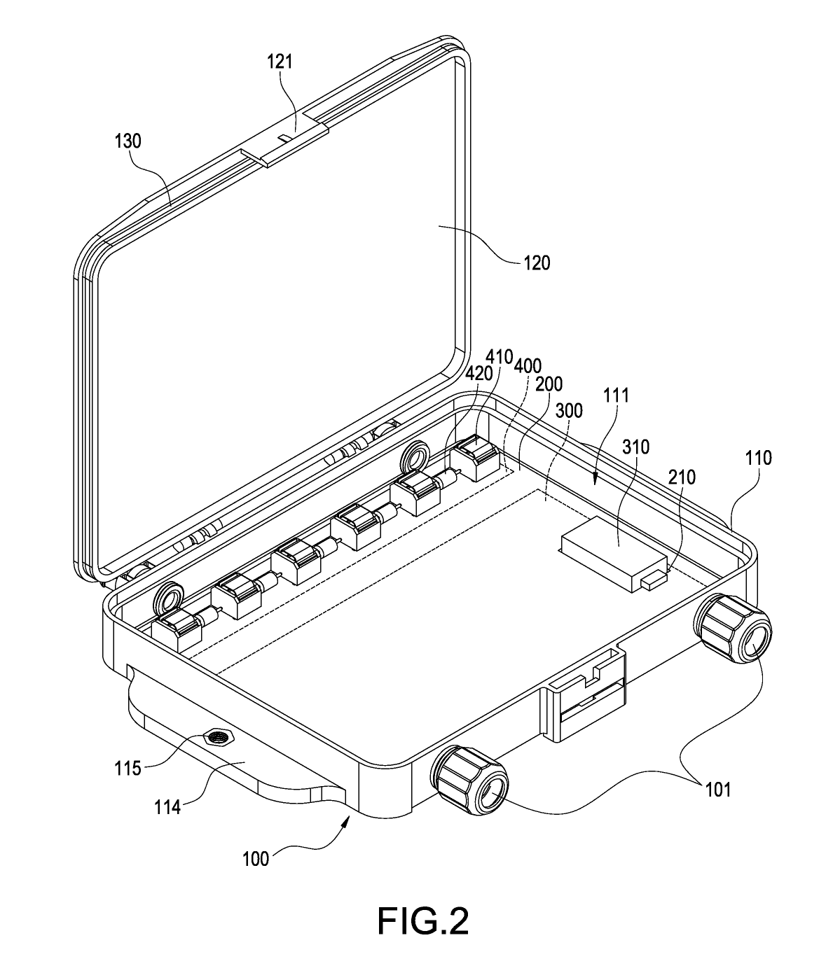

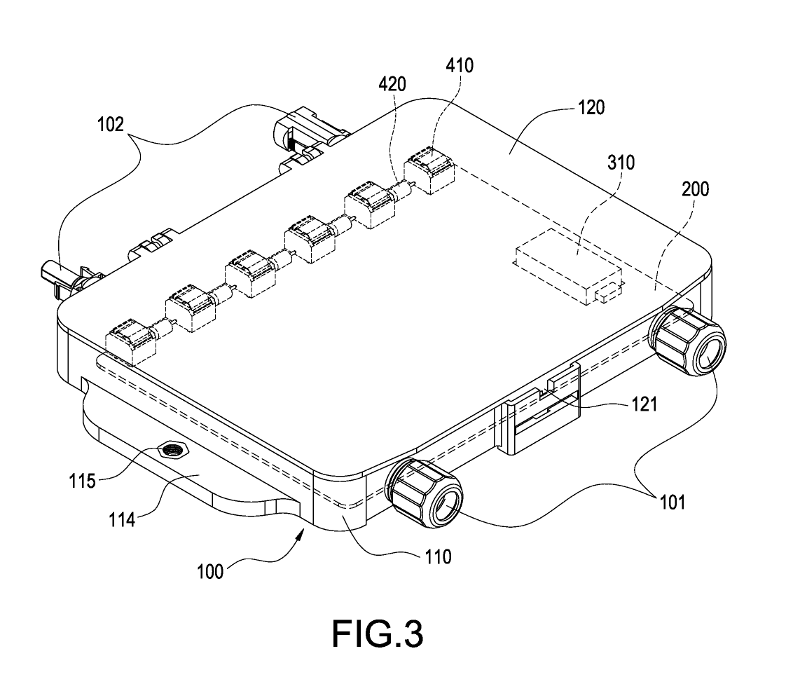

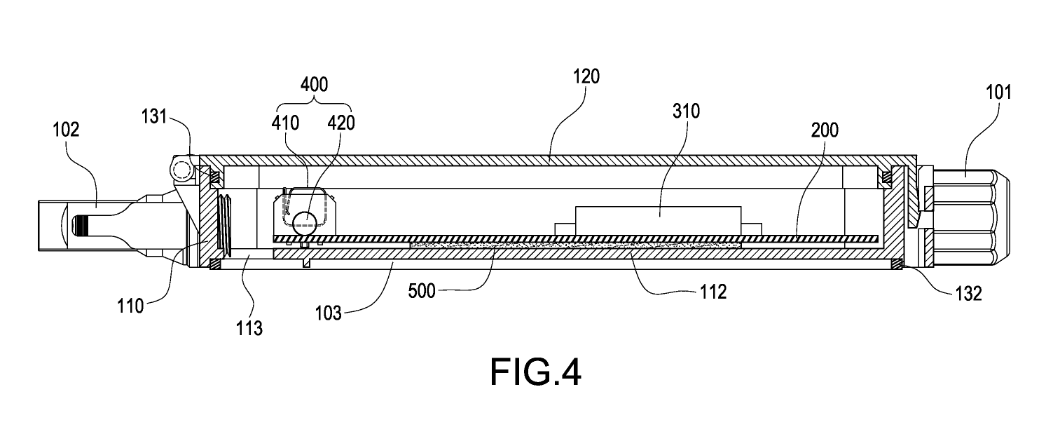

Please refer to FIGS. 1-4. A preferred embodiment of the present invention provides an inverter module which is electrically connected to a photovoltaic panel absorbing the sunlight energy and converting to a DC current. The DC current is converted to an AC current using the inverter module of the present invention for further use. In the embodiment, the inverter module of the present invention comprises a housing 100 and a PCB 200.

The housing 100 comprises a box body 110 and a cover body 120. The box body 110 which is substantially rectangular has an opening 111 and a base panel 112 opposite to the opening 111. A long and narrow through hole is cut and disposed on the base panel 112. A pair of output ports 101 and a pair of input ports are disposed on an outer side of the box body 110. An outer side of the base panel 112 is hollowed inward to form a heat dissipating space 103 and an outer edge of the base panel 112 extends outward to form a locking panel 114.

The cover body 120 is used to cover the opening 111. Preferably, the cover body 120 is hinged to a side of the opening 111 and a clamping structure 121 is used to clamp the box body 110 firmly at the opposite side of the opening 111. A waterproof gasket 131 is disposed between the box body 110 and the cover body 120. When the cover body 120 covers the opening 111, the waterproof gasket 131 is clamped between the cover body 120 and the opening 111, thus sealing the housing 100. A locking hole 115 is formed on the above-mentioned locking panel 114; therefore, the housing 100 can be screwed and attached to the photovoltaic panel via the locking hole 115.

The PCB 200, substantially rectangular, is received within the housing 100 and preferably is fixed to the inner side of the base panel 112 of the box body 110. A side of the PCB 200 is disposed adjacent to the through hole 113. An inverter circuit 300 and a connection circuit 400 are welded and configured independently in separate areas. The connection circuit 400 is arranged along the side of the through hole 113 and comprises a plurality of conductive terminals 410 and a plurality of diodes 420. At least one cut opening 210 is formed on the PCB 200.

The inverter circuit 300 is electrically connected to the input ports 101 and the output ports 102. The inverter circuit 300 comprises a plurality of electronic components 310 (e.g., capacitors). The cut opening 210 of the PCB 200 is used to receive the electronic components 310 with larger volume.

Each of the conductive terminals 410 is preferably made of a flexible metal piece bent to have a clamp shape; however, the shape of the conductive terminals 410 of the present invention is not limited. The conductive terminals 410 are arranged in a row along either side of the PCB 200 which is preferably disposed adjacent to a long side of the through hole 113 such that the conductive terminals 410 are disposed adjacent to the through hole 113. Each of the conductive terminals 410 is electrically connected to the inverter circuit 300. Also, each diode 420 is disposed between and electrically connected to the two neighboring conductive terminals (410) thereof, whereby to prevent the reverse current through the conductive terminals 410.

A thermal pad 500 is preferably attached to the PCB 200. One side of the thermal pad 500 is attached to the PCB 200; the other side of the thermal pad 500 is attached to the base panel 112 of the box body 110. Thus, the heat generated during the operation of the inverter circuit 300 can be transferred to the base panel 112 and the dissipated out of the housing 100 through the heat dissipating space 103.

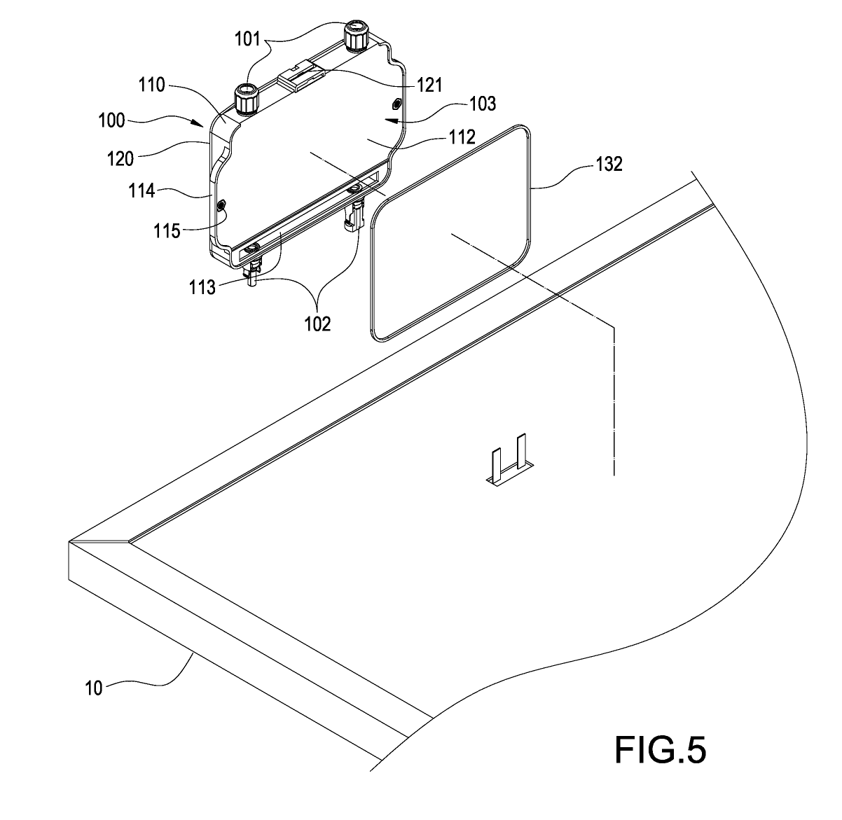

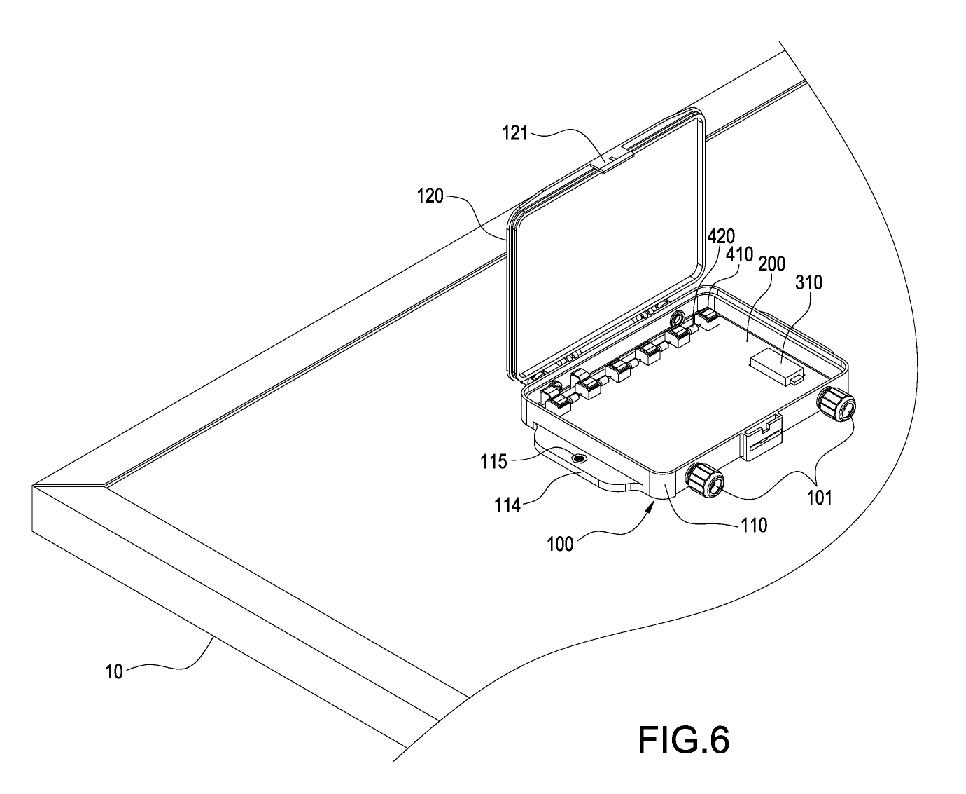

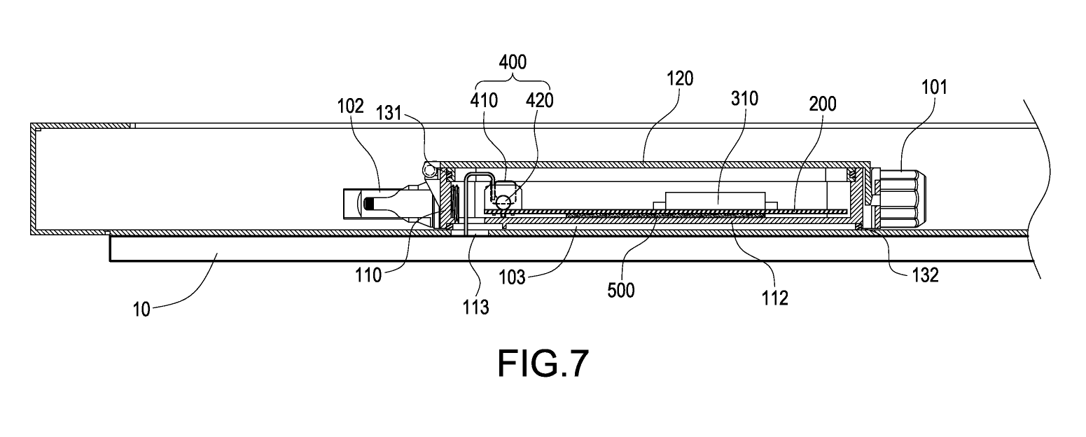

Please refer to FIGS. 5-7, which show that the inverter module of the present invention is arranged with the photovoltaic panel 10. The former is electrically connected to the latter using the conductive terminals 410. The photovoltaic panel 10 converts the generated DC current which flows into the inverter circuit 300 through the conductive terminals 410. The DC current is converted to the AC current via inverter circuit 300 and then outputted through the output port 101 for further use. Preferably, a waterproof gasket 132 can be disposed between the box body 110 and the photovoltaic panel 10.

In addition, if the photovoltaic panel 10 has already been equipped with a junction box, the inverter module of the present invention can be electrically connected to the photovoltaic panel 10 through the electrical connection from the input port 102 to the junction box of the photovoltaic panel 10, instead of through that from the conductive terminals 410 to the photovoltaic panel 10.

The inverter module of the present invention integrates the inverter circuit 300, the conductive terminals 410, and the diodes 420 into the same PCB 200, thus omitting the structure of the junction box. Consequently, the space occupied by the inverter module is reduced, and manufacture and installation thereof are made easier than the related art. Moreover, in the inverter module of the present invention, the electronic component 310 is disposed in the cut opening 210 of the PCB 200, thus reducing the thickness of the housing 100.

The above description is only about preferred embodiment of the present invention, but not to limit the scope of claims of the present invention. Other equivalent variations according to the claimed spirit of the present invention should be embraced within the claimed scope of the present invention.

What is claimed is:

1. An inerter module, comprising:
a housing (100) having a through hole (113); and
a PCB (200) received within the housing (100), wherein an inverter circuit (300) and a connection circuit (400) comprising a plurality of conductive terminals (410) and a plurality of diodes (420) are welded on a side of the PCB (200), wherein the conductive terminals (410) are arranged in a row and adjacent to the through hole (113), wherein each of the conductive terminals (410) is electrically connected to the inverter circuit (300), wherein each of the diodes (420) is disposed between and electrically connected to the two neighboring conductive terminals (410) thereof.

2. The inerter module according to claim 1, wherein the housing (100) comprises a box body (110) and a cover body (120), the box body (110) has an opening (111) and a base panel (112) opposite to the opening (111), and the cover body (12) is hinged to a side of the opening (111) to cover the opening (111).

3. The inerter module according to claim 2, wherein the through hole (113) is cut and disposed in the box body (110).

4. The inerter module according to claim 2, wherein the through hole (113) is cut and disposed on the base panel (112) of the box body (110).

5. The inerter module according to claim 2, wherein an outer edge of the base panel (112) extends to form a locking panel (114) having a locking hole (115) thereon.

6. The inerter module according to claim 2, wherein an outer side of the base panel (112) of the box body (110) is hollowed inward to form a heat dissipating space (103).

7. The inerter module according to claim 1, wherein a thermal pad (500) is attached to the PCB (200) and contacts the housing (100).

8. The inerter module according to claim 1, wherein a cut opening (210) is formed on the PCB (200), wherein the inverter circuit (300) comprises a plurality of electronic components (310), one of which is disposed in the cut opening (210).

9. The inerter module according to claim 2, wherein a pair of output ports (101) is disposed on an outer side of the box body (110), and each of the output ports (101) is electrically connected to the inverter circuit (300).

10. The inerter module according to claim 2, wherein a side of the PCB (200) is disposed adjacent to the through hole (113), the conductive terminals (410) are arranged in a row along the side of the PCB (200), and the inverter circuit (300) and the connection circuit (400) are configured in separate areas.
